(19) United States
(12) Patent Application Publication
(10) Pub. No.: US 2023/0320046 A1
(43) Pub. Date: Oct. 5, 2023

(54) AIRBRIDGE, SUPERCONDUCTING CIRCUIT APPARATUS AND METHOD OF FABRICATION THE SAME

(71) Applicant: NEC Corporation, Tokyo (JP)

(72) Inventors: Ayuka TADA, Tokyo (JP); Tetsuro Sato, Tokyo (JP)

(73) Assignee: NEC Corporation, Tokyo (JP)

(21) Appl. No.: 18/102,209

(22) Filed: Jan. 27, 2023

(30) Foreign Application Priority Data
Mar. 31, 2022 (JP) 2022-060283

(51) Int. Cl. H05K 9/00; H01B 12/02

(52) U.S. Cl. CPC H05K 9/00; H01B 12/02

(57) ABSTRACT

An airbridge includes first and second bridge abutments contacted with first and second conductors opposing each other via a gap, with a third conductor extending therein, first and second bridge piers rising from the first and second bridge abutments, and a bridge girder part supported by the first and second bridge piers in air to stride over the third conductor, wherein first and intersection edges, at which the first and second bridge abutment intersect with bases of the first and second bridge pier, is of a convex shape protruding toward one side from first and second virtual straight lines each connecting end points at which both sides of the first and second bridge abutments intersect with the first and second intersection edge, respectively.

### CROSS REFERENCE TO RELATED APPLICATIONS

This application is based upon and claims the benefit of the priority of Japanese patent application No. 2022-060283, filed on Mar. 31, 2022, the disclosure of which is incorporated herein in its entirety by reference thereto.

### FIELD

The present invention relates to an airbridge, a superconducting circuit apparatus and a method of fabrication the same.

### BACKGROUND

A superconducting quantum circuit includes, as a basic element, a superconducting resonator which includes an inductor, a capacitor and a SQUID (Super Quantum Interference Device) having one or more Josephson junctions in a loop, wherein the inductor, the capacitor and the SQUID are each made of a superconducting metal or alloy. The Josephson junction is a tunnel junction in which a thin insulating film is sandwiched between superconductors. The Josephson junction behaves as a non-linear inductor. A resonant frequency of the superconducting resonator can be varied by supplying a current (dc or microwave current) from a current control part to modulate a magnetic flux penetrating through the loop of the SQUID. In the superconducting quantum circuit, a coplanar line (coplanar waveguide) provided with a signal line and a pair of ground planes arranged in parallel across the signal line is used. In a single superconducting quantum circuit chip with a plurality of SQUIDs provided thereon, there may be a problem of a crosstalk that a current applied to one SQUID to generate a magnetic flux penetrating through the one SQUID, is applied also to one or more SQUIDs other than the one SQUID. This kind of crosstalk is thought to be partly due to a fact that the ground plane is divided into two separate ground planes, thus a charge distribution (current) being generated in the ground plane. As a measure to prevent the crosstalk, an airbridge (denoted also as “air bridge” or “air-bridge”) is used, for example. An airbridge is configured to stride over a wiring between a pair of wirings and connect the pair of wirings in a wiring layer (conductor layer) formed on a substrate. For example, patent Literatures (PTLs) 1 and 2, disclose a superconducting airbridge striding a signal line of the coplanar waveguide to connect ground planes arranged on both sides of the signal line.

FIG. 8A and FIG. 8B schematically illustrate a typical example of an airbridge of a related technology. FIG. 8A is a schematic plan view on a XY-plane seen from a Z-axis direction, and FIG. 8B is a schematic cross-sectional view along a line A-A in FIG. 8A. As illustrated in FIG. 8A and FIG. 8B, an airbridge 130 has a hollow structure in which first and second bridge piers 132A and 132B support both ends of a bridge girder part 133 in air such that the bridge girder part 133 strides (i.e., bridges) over a signal conductor 121. The first and second bridge piers 132A and 132B rise respectively from first and second bridge abutments 131A and 131B contacting with (abutting to) ground conductors (ground patterns) 122A and 122B respectively arranged via gaps on both sides of a conductor (signal conductor) 121. In a superconducting quantum circuit (chip), the signal conductor 121, the ground conductors 122A and 122B, and each part of the airbridge 130 are made of a superconducting material, and a substrate 1 is made of e.g., silicon (Si). It is noted that in FIG. 8A and FIG. 8B, each part of the airbridge 130 is denoted using a name corresponding to each member of the structure of a general bridge and these names are used for clarification of explanation of the structure. In an example illustrated in FIG. 8A and FIG. 8B, the first and second bridge piers 132A and 132B and the bridge girder part 133 are illustrated as a configuration in which the first and second bridge piers 132A and 132B intersect the bridge girder part 133 at a given angle (obtuse angle, but inclusive of 90 degree). However, the first and second bridge piers 132A and 132B and the bridge girder part 133 may form an arch with a continuous curve, like an arched bridge.

A yield of a chip with the airbridge illustrated in FIG. 8A and FIG. 8B is rather low due to disappearance or collapse of bridges during a fabrication process.

In addition to reduction of the crosstalk, an airbridge wiring using air as an interlayer insulator in widely used to reduce a parasitic capacitance between wirings in forming transmission lines crossing each other on a Monolithic Microwave Integrated Circuit (MMIC). For example. PTL 3 discloses a configuration in which an overall shape of an airbridge wiring has an upward convex curvature in an arch shape with a transverse section of a shape a downward convex curvature to provide a long airbridge itself with a mechanical strength against deflection in a MMIC chip.
PTL1: Japanese Patent No. 6437607
PTL2: Japanese Unexamined Patent Application Publication (Translation of PCT Application) No. 2020-532866
PTL3: Japanese Unexamined Patent Application Publication No. 2008-270617

### SUMMARY

It is an object of the present disclosure to provide an airbridge, a superconducting circuit apparatus and a method of fabrication the same in which a strength of a bridge pier portion is increased such that an overall strength of the airbridge can be increased in a simple configuration.

According to one aspect of the present disclosure, there is provided an airbridge including first and second bridge abutments contacted with first and second conductors, respectively, the first and second conductors opposing each other via a gap, wherein a third conductor is provided extending in the gap, the first to third conductors each provided on a substrate; first and second bridge piers rising from the first and second bridge abutments, respectively; and a bridge girder part having both ends supported by the first and second bridge piers in air, the bridge girder part striding over the third conductor.

A first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

According to another aspect of the present disclosure, there is provided a superconducting circuit apparatus including first and second conductors arranged opposing each other; a third conductor extended in a gap between the first and second conductors, the first, second and third conductors each made of a superconducting material; and an airbridge striding over the third conductor to bridge first and second conductors.

The airbridge includes first and second bridge abutments contacted with first and second conductors, respectively, the first and second conductors opposing each other via a gap, wherein a third conductor is provided extending in the gap, the first to third conductors provided on a substrate; first and second bridge piers rising from the first and second bridge abutments, respectively; and a bridge girder part having both ends supported by the first and second bridge piers in air, the bridge girder part striding over the third conductor.

A first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

According to still another aspect of the present disclosure, there is provided a method of fabrication a superconducting circuit apparatus including first and second conductors arranged opposing each other;
a third conductor extended in a gap between the first and second conductors, the first, second and third conductors each made of a superconducting material; and
an airbridge striding over the third conductor to bridge first and second conductors, the airbridge including:
first and second bridge abutments contacted with the first and second conductors, respectively;
first and second bridge piers rising from the first and second bridge abutments, respectively; and
a bridge girder part having both ends supported by the first and second bridge piers in air, the bridge girder part striding over the third conductor. The method includes
(A) forming first and second vias each having convex shaped bottom apertures protruding toward one side at locations corresponding to locations of formation of the first and second bridge abutments, respectively, on a sacrificial layer formed on a superconducting wiring pattern on a substrate;
(B) depositing a superconducting film, as a component of the airbridge, on the sacrificial layer; and
(C) removing the sacrificial layer after patterning the superconducting film of the component of the airbridge, to produce the airbridge,
wherein a first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and
a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

According to the present disclosure, it is possible to provide an airbridge in which the strength of the bridge pier portion is increased so that the overall strength of the airbridge can be increased in a simple configuration.

### BRIEF DESCRIPTION OF THE DRAWINGS

FIG. 1A is a schematic plan view of a configuration according to an example embodiment.

FIG. 1B is a schematic cross-sectional view of the configuration according to the example embodiment.

FIG. 2A to FIG. 2H are diagrams schematically illustrating an example of fabrication processes according to the example embodiment.

FIG. 3A is a diagram schematically illustrating a configuration according to an example embodiment.

FIG. 3B is a diagram schematically illustrating a configuration according to an example embodiment.

FIG. 3C is a diagram schematically illustrating a configuration according to an example embodiment.

FIG. 4A is a diagram schematically illustrating a configuration according to a comparative example.

FIG. 4B is a diagram schematically illustrating a configuration according to a comparative example.

FIG. 4C is a diagram schematically illustrating a configuration according to a comparative example.

FIG. 5A is a diagram schematically illustrating a configuration according to another example embodiment.

FIG. 5B is a diagram schematically illustrating a configuration according to another example embodiment.

FIG. 5C is a diagram schematically illustrating a configuration according to another example embodiment.

FIG. 6 is a diagram schematically illustrating an example of a configuration of a superconducting circuit according to an example embodiment.

FIG. 7A is a diagram schematically illustrating an example of a configuration according to another example embodiment.

FIG. 7B is a diagram schematically illustrating an example of a configuration according to another example embodiment.

FIG. 7C is a diagram schematically illustrating an example of a configuration according to another example embodiment.

FIG. 8A is a schematic plan view of a configuration of a technology.

FIG. 8B is a schematic cross-sectional view of the configuration of the related technology.

### EXAMPLE EMBODIMENTS

PTL 3 discloses a configuration in which the transverse sectional shape of the bridge pier portion is in the form of a downward convex curvature to provide the airbridge itself with a mechanical strength against deflection, which requires complicated and time-consuming fabrication. The above issue is one example, but according to the present disclosure, it is possible to provide an airbridge in which the strength of the bridge pier portion is increased so that the overall strength of the airbridge can be increased in a simple configuration.

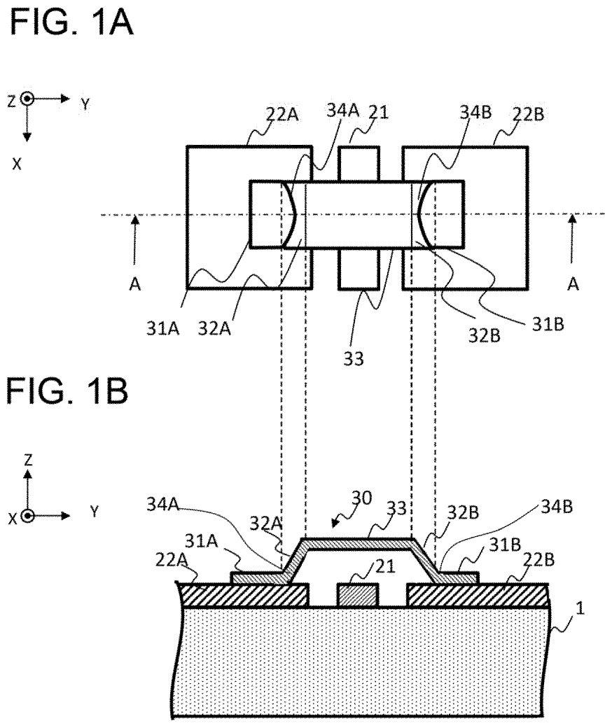

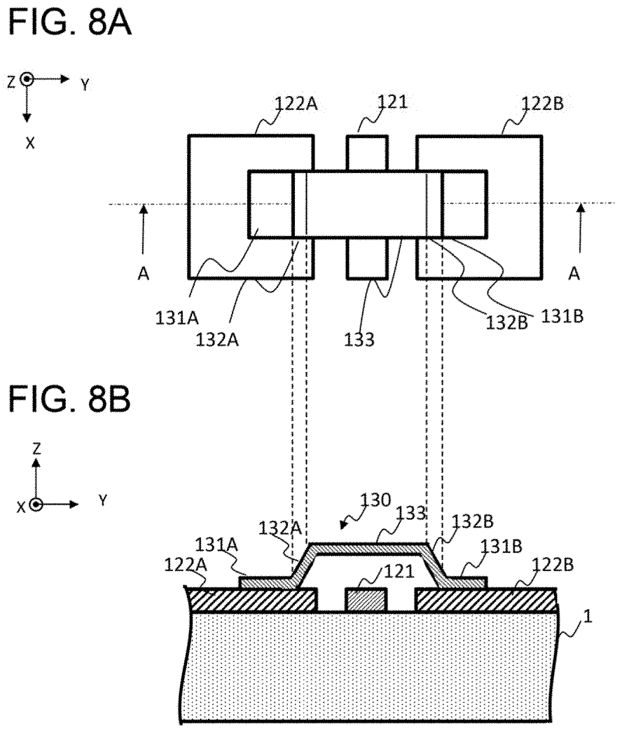

The following describes several example embodiments with reference to the drawings. FIG. 1A to FIG. 1C illustrate an airbridge 30 according to one example embodiment. FIG. 1A is a schematic plan view on a XY-plane seen from a Z-axis direction, and FIG. 1B is a schematic cross-sectional view along a line A-A in FIG. 1A. FIG. 1A and FIG. 1B are corresponding to FIG. 8A and FIG. 8B, respectively. Referring to FIG. 1A and FIG. 1B, a superconducting circuit apparatus has a structure in which a third conductor (signal conductor) 21 is disposed between a first conductor 22A and a second conductor 22B arranged opposing each other on a substrate 1. The first and second conductors 22A and 22B each are a ground plane (planar ground pattern) formed on a wiring layer on the substrate 1. The first and second conductors 22A and 22B, and the third conductor 21 are made of a superconducting material. The airbridge 30 includes first and second bridge abutments 31A and 31B, and first and second bridge piers 32A and 32B. The first and second bridge abutments 31A and 31B are joined in contact with the first and second conductors 22A and 22B. The first and second bridge piers 32A and 32B rise from edges 34A and 34B of the first and second bridge abutments 31A and 31B, respectively to support at tops thereof a bridge girder part 33 in the air. The bridge girder part 33 strides (i.e., bridges) the third conductor 21 in an air. An intersection edge (boundary) 34A, where the first bridge abutment 31A intersects with a base of the first bridge pier 32A is of a convex shape, seen from above, protruded toward the second bridge abutment 31B against a virtual straight line connecting end points of the intersection edge 34A at which the intersection edge 34A intersects with both sides of the first bridge abutment 31A. Also, an intersection edge (border) 34B, where the second bridge abutment 31B intersects with a base of the second bridge pier 32B is of a convex shape, seen from above, protruded toward the first bridge abutment 31A against a virtual straight line connecting end points of the intersection edge 34B at which the intersection edge 34B intersects with both sides of the second bridge abutment 31B. The convex shape is preferably a convex curve, and planar shapes of the first and second bridge abutments 31A and 31B, seen from above, are formed in a D-shaped. The airbridge 30 is also made of a superconducting material.

A transverse cross-section shape of the bridge girder part 33 is approximately a rectangular, but may, as a matter of course, have curvatures, etc., due to fabrication. In FIG. 1B, the first and second bridge piers 32A and 32B intersect at predetermined angles at both ends of the bridge girder part 33, simply for explanation purposes, but may, as a matter of course, have an arch shape of a smooth continuous curve.

In FIG. 1B, the substrate is made of silicon. Other electronic material(s) selected from a group including germanium, sapphire, and compound semiconductor materials such as Group IV (GeSn, etc.), Group III-V (GaAs, GaN, GaP, GaSb, InAs, InP, InS, etc.), and Group II-VI (ZnS, ZnSe)) may be used for the substrate. Single crystal is preferable, but polycrystalline or amorphous may also be used.

A superconductive conductor is composed of a superconducting material such as niobium (Nb). The superconducting material is not limited to niobium (Nb), but may include at least one selected from a group including niobium nitride, aluminum (Al), indium (In), lead (Pb), tin (Sn), rhenium (Re), palladium (Pd), titanium (Ti), titanium nitrides, tantalum (Ta), tantalum nitrides, and an alloy with a superconducting property including at least one selected therefrom.

The first and second conductors 22A and 22B, and the third conductor (signal conductor) 21 may be made of Nb. The airbridge 30 (the first and second bridge abutments 31A and 31B, the first and second bridge piers 32A and 32B, and the bridge girder part 33) may be made of a different material from Nb, e.g., Al.

A length of the airbridge 30 may be set to a value corresponding to a spacing between the first and second conductors 22A and 22B. As a non-limiting example, a width of the third conductor (signal conductor) 21 may be set at an extent of about 2-24 μm (micrometer), a gap between the first conductor 22A and the third conductor 21 and a gap between the second conductor 22B and the third conductor can be at an extent of about 10 μm, widths of the first and second bridge abutments 31A and 31B of the airbridge 30 may be at an extent of about 30 μm length thereof may be at an extent of about 40 μm, and a distance between the first and second bridge piers 32A and 32B may be at an extent from about 30 to 70 μm. A height of the airbridge 30 is a implementation (design) specific parameter and is set to a value, for example, decided by a thickness of a sacrificial layer, which will be later described.

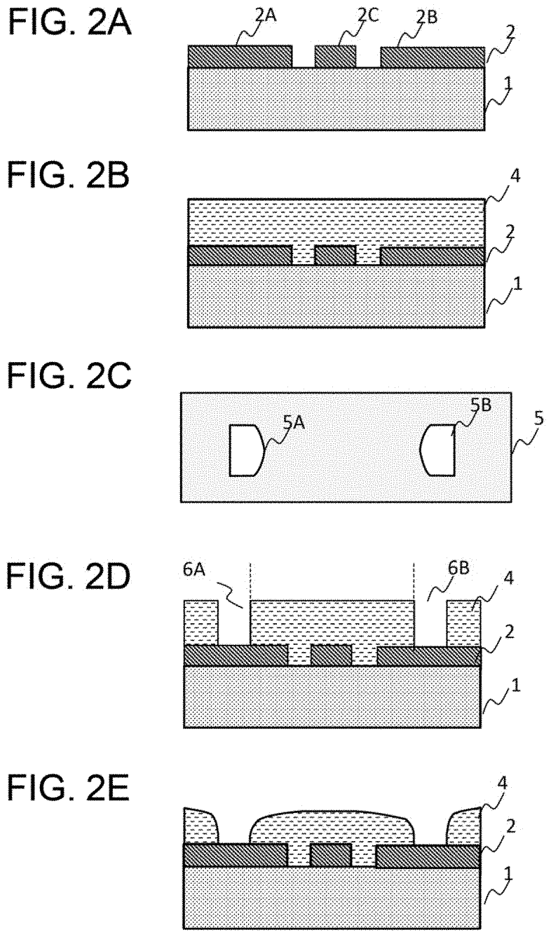

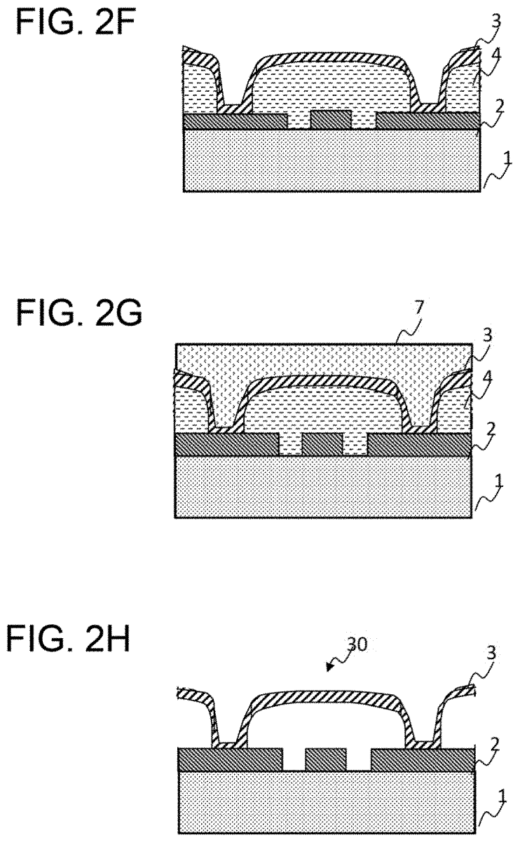

FIG. 2A to FIG. 2H schematically illustrate a process cross sectional diagram of an example of processes related to manufacture of the airbridge 30 in a case when a quantum chip according to the example embodiment is fabricated using a semiconductor process. FIG. 2A to FIG. 2H are divided in two drawing sheets only for the sake of convenience of the drawing.

Referring to FIG. 2A, a superconductive conductor film 2, such as Nb, etc., is deposited on an entire surface of a substrate 1 (silicon), and a wiring pattern is formed by exposure and development (photolithography) and/or etching, for example. In FIGS. 2A, 2A, 2B and 2C correspond to the first conductor 22A, the second conductor 22B and the third conductor (signal conductor) 21 illustrated in FIG. 1A, respectively.

Next, referring to FIG. 2B, a sacrificial layer 4 is formed (coated) on the entire surface of the substrate 1. The sacrificial layer 4 is made of, for example, a photoresist (e.g., organic polyimide). The sacrificial layer 4 may be silicon dioxide (SiO₂) or the like.

Next, referring to FIG. 2C, a mask pattern of a photomask 5 for pattern forming of vias (blind vias) in the sacrificial layer 4 is schematically illustrated. Vias with D-shaped bottoms are formed in the sacrificial layer 4 in order to form first and second bridge abutments (contact portion) 31A and 31B of an airbridge 30. In the photomask 5, D-shaped apertures 5A and 5B are arranged opposing each other at the positions where the first and second bridge abutments (contact portion) 31A and 31B of the airbridge 30 are formed. The apertures 5A and 5B are D-shaped, with opposing edges each protruding in an arc fashion. The apertures 5A and 5B are as a matter of course, not limited to the D-shape, but may be any convex curved shape.

Next, referring to FIG. 2D, by exposing and developing the sacrificial layer 4 (photoresist) using this photomask 5, vias 6A and 6B reaching the superconductive conductor film 2 are formed. The shape of bottom surface of the vias 6A and 6B corresponds to the apertures 5A and 5B in FIG. 2C. In a case where the sacrificial layer 4 is SiO2, the vias 6A and 6B are formed by exposure, development and etching of the sacrificial layer 4 using the photomask 5.

Next, referring to FIG. 2E, the sacrificial layer 4 is reflowed e.g., by heat treatment of the substrate 1. In a case where the sacrificial layer 4 is SiO₂, for example, the sacrificial layer 4 with the shape shown in FIG. 2E is obtained by rounding (removing) corners of the sacrificial layer 4 by anisotropic dry etching.

Next, referring to FIG. 2F, a superconducting material (superconductive conductor film) 3, which serves as the airbridge 30, is deposited on the substrate 1 by sputtering or the like. As a non-limited example, the superconducting material 3 is made of aluminum (Al). A thickness of the superconducting material 3 may be, for example, of an extent of several hundred nanometers (nm) not more than 1 μm.

Next, referring to FIG. 2G, a photoresist 7 is coated and a pattern of the airbridge is formed by exposure and development.

With etching of Al using the photoresist 7 left on the airbridge as a mask, the airbridge 30 is formed on a wiring pattern formed of the superconductive conductor film 2.

Referring to FIG. 2H, the photoresist 7 and the sacrificial layer 4 (photoresist) are removed by ashing (e.g., oxygen plasma ashing) etc., and the remaining photoresist is removed with an organic solvent (liquid) to form a three-dimensional airbridge 30.

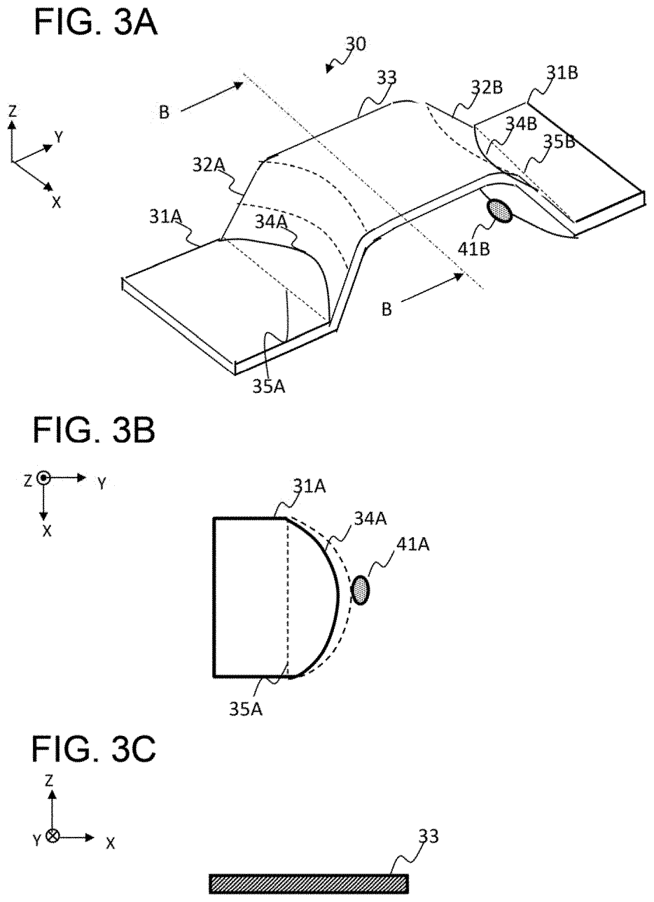

FIG. 3A is a perspective view schematically illustrating the airbridge 30 according to an example embodiment. Broken line (dashed line) 35A designates a virtual straight line that connects end points of the intersection edge 34A at which the intersection edge 34A intersects with both sides of the first bridge abutment 31A, wherein the intersection edge 34A is an edge (boundary) that the first bridge abutment 31A intersects with a base of the first bridge pier 32A. As illustrated in FIG. 3A, the intersection edge 34A of the first bridge abutment 31A is protruded (projected) toward an opposite side of the first bridge abutment 31A (i.e., a side of the second bridge abutment 31B) against the virtual straight line 35A. Broken line (dashed line) 35B designates a virtual straight line that connects end points of the intersection edge 34B at which the intersection edge 34B intersects with both sides of the second bridge abutment 31B, wherein the intersection edge 34B is an edge (boundary) that the second bridge abutment 31B intersects with a base of the second bridge pier 32B. The intersection edge 34B of the second bridge abutment 31B is protruded (projected) toward an opposite side of the second bridge abutment 31B (i.e., a side of the first bridge abutment 31B) against the virtual straight line 35A.

A surface of the first bridge pier 32A (a surface of a sloping section) rising from the intersection edge 34A of the first bridge abutment 31A is concave on a central portion, corresponding to a shape of the intersection edge 34A which is a base of the first bridge pier 32A. The degree of concavity at a center portion of the surface of the first bridge pier 32A is mitigated as a height of the first bridge pier 32A increases, approaching almost flat at the top of the first bridge pier 32A (sloping section). This corresponds to a shape of a bottom surface of each of the vias 6A and 6B illustrated in FIG. 2D, reference to which is made to in the description of the fabrication process of the airbridge 30 and a shape of a side surface of the sacrificial layer 4 after reflowing illustrated in FIG. 2E. The shape of the second bridge pier 32B of the second bridge abutment 31B is similar. A shape of a cross section (transverse cross-section) cut along a line B-B of the bridge girder part 33 is approximately rectangular as illustrated in FIG. 3C as a schematic side cross-sectional view.

FIG. 3B illustrates a residue 41A of a sacrificial layer at a back surface side of the intersection edge 34A of the first bridge abutment 31A. The back surface of the intersection edge 34A of the first bridge abutment 31A, i.e., a back surface of the first bridge pier 32A protrudes convexly toward the second bridge pier 32B of the second bridge abutment 31B opposite thereto. Due to this structure, in a removal process of the photoresist 7 and the sacrificial layer 4 illustrated in FIG. 2H, each of backs of the intersection edges 34A and 34B of the first and second bridge abutments 31A and 31B is convex, which makes it easier for organic solvents to enter and leave the area and makes it difficult for the residue 41A to remain. Photoresist residues, etc. on a wafer may be a cause of dielectric loss in a superconducting quantum circuit element, and thus the residues preferably are as little as possible.

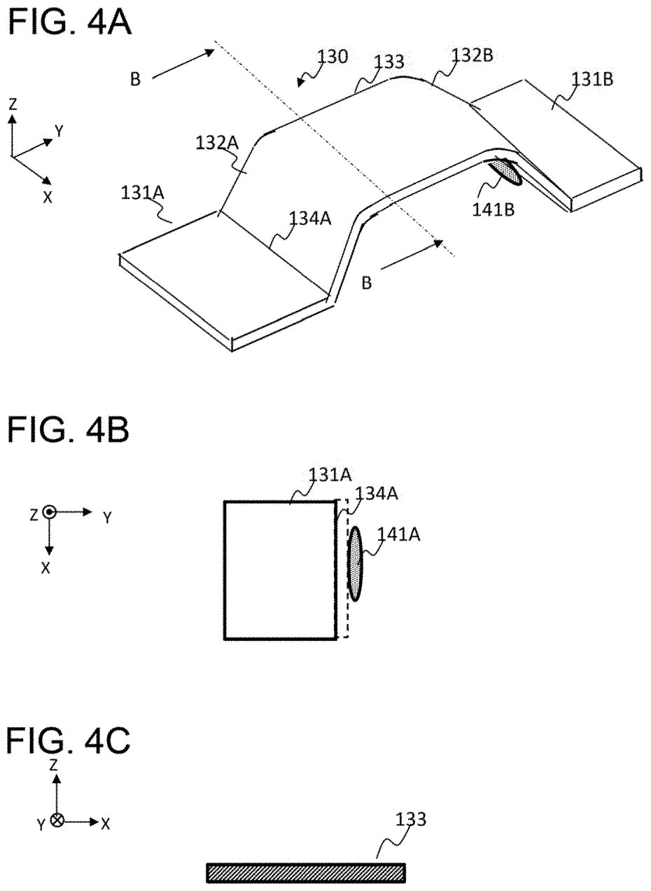

FIG. 4A schematically illustrates, as a comparative example, a perspective view of an airbridge 130 of the related technology described with reference to FIGS. 8A and 8B. FIG. 4B schematically illustrates a residue 141A of a sacrificial layer at a back surface side of an intersection edge 134A of a first bridge abutment 131A thereof. As illustrated in FIG. 4A, the intersection edge 134A of the first bridge abutment 131A is a straight-line connecting end points of two sides of the first bridge abutment 131A and corresponds to the virtual straight line 35A, which is illustrated by the broken line in FIG. 3A. In a removal process of the photoresist and the sacrificial layer illustrated in FIG. 2H, at backs of the intersection edges 134A and 134B of the first and second bridge abutments 131A and 131B, as well as on a back surface of the first and second bridge piers 132A and 132B, residues 141A and 141B are likely to remain, respectively. Removal process of residues from the photoresist/sacrificial layer is time-consuming.

FIG. 4C is a schematic cross-sectional view along a line B-B of a bridge girder part 133 illustrated in FIG. 4A. As illustrated in FIG. 3C and FIG. 4C, the cross-section of the bridge girder part 33 of the example embodiment illustrated in FIG. 3A is almost identical to the cross-section of the bridge girder part 133 of the related art illustrated in FIG. 4A.

As a configuration illustrated in FIG. 3A, according to the example embodiment, a configuration of the airbridge 30 is designed to enhance a strength of each of the first and second bridge piers 32A and 32B, which are base portions of the airbridge 30, and thus enhance an entire strength of the airbridge 30. This is because an apparent cross-sectional secondary moment of each of the first and second bridge piers 32A and 32B illustrated in FIG. 3A is significantly larger than that of each of the first and second bridge piers 132A and 132B of a flat plate type illustrated in FIG. 4A.

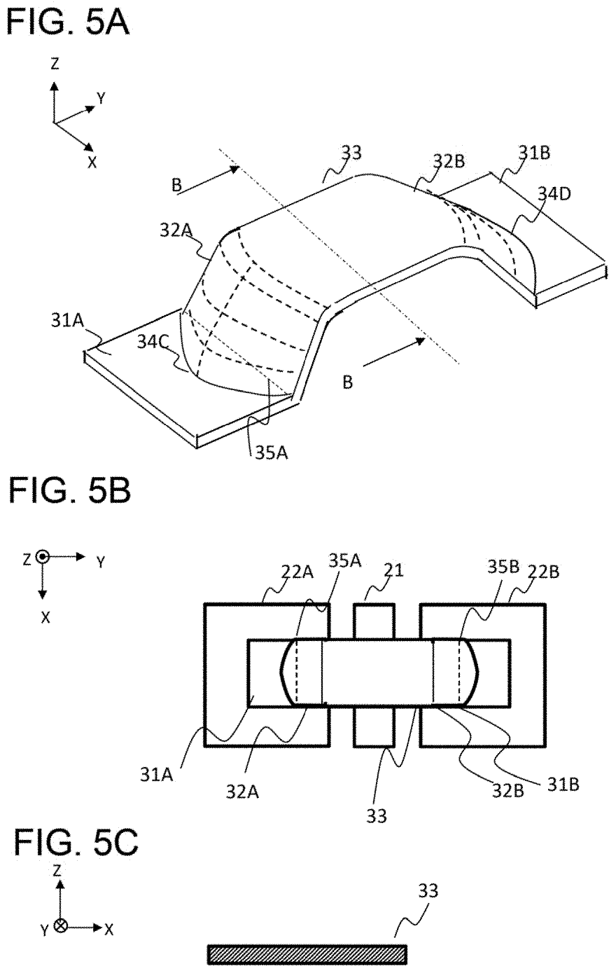

FIG. 5A to FIG. 5C illustrate another example embodiment. FIG. 5A and FIG. 5C are corresponding to FIG. 3A and FIG. 3C, respectively. FIG. 5B is a schematic plan view of an airbridge illustrated in FIG. 5A seen from above (Z-axis direction). Referring to FIG. 5B, a broken line 35A represents a virtual straight line that connects intersection points at which both sides of the first bridge abutment 31A intersect both end points of the intersection edge 34C, in the first bridge abutment 31A. An intersection edge 34C of the first bridge abutment 31A is protruded toward a side of the first bridge abutment 31A opposing the An intersection edge 34C against the virtual straight line 35A, wherein the intersection edge 34C is an edge (boundary) on which the first bridge abutment 31A and the first bridge pier 32A intersect. It can also be said that the intersection edge 34C of the first bridge abutment 31A is curved and concave against the virtual straight line 35A.

A surface of the first bridge pier 32A (a surface of a sloping section) rising from the intersection edge 34C of the first bridge abutment 31A is protruded (convex) in a center portion, in correspondence with a shape of the intersection edge 34C, which is also the base of the first bridge pier 32A. The protrusion degree thereof is mitigated as a height of the first bridge pier 32A increases, approaching almost flat at the top of the first bridge pier 32A (sloping section). This corresponds to a shape of a bottom surface of each of the vias 6A and 6B illustrated in FIG. 2D, referred to in the description of the fabrication process of the airbridge 30 and a shape of a side surface of the sacrificial layer 4 after reflowing illustrated in FIG. 2E. A shape of a cross-section (transverse cross-section) cut along a line B-B of the bridge girder part 33 is approximately rectangular as illustrated in FIG. 5C as a schematic side cross-sectional view. The shape of the second bridge pier 32B of the second bridge abutment 31B is similar.

In the present variation of the example embodiment, the back surface of the intersection edge 34A of the first bridge abutment 31A, i.e., a back surface of the first bridge pier 32A is concave. Therefore, in a removal process of the photoresist 7 and the sacrificial layer 4 illustrated in FIG. 2H, it may be said that the residue 41A, which is a residue of the photoresist 7 and/or the sacrificial layer 4, is likely to remain at the backs of the intersection edges 34A and 34B of the first and second bridge abutments 31A and 31B and at the back surface of the first and second bridge piers 32A and 32B. However, a configuration of the airbridge 30 according to the present variation of the example embodiment is designed to enhance the strength of the first and second bridge piers 32A and 32B, as compared with that of the configuration illustrated in FIG. 4A. This is because apparent cross section secondary moments of the first and second bridge piers 32A and 32B are significantly larger than those of the first and second bridge piers 132A and 132B of the flat plate type illustrated in FIG. 4A.

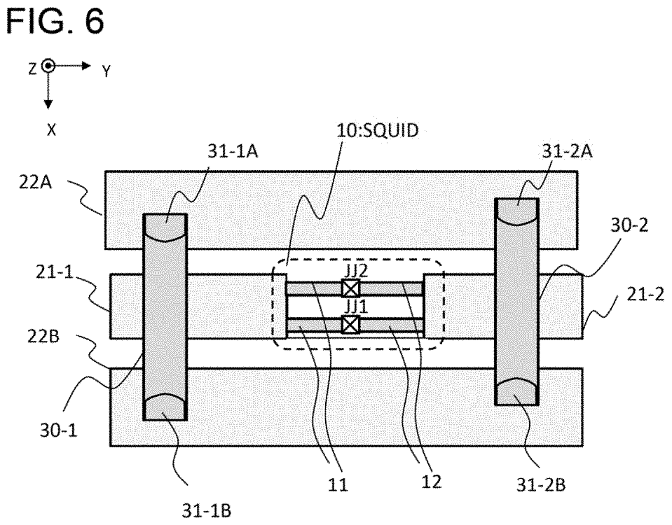

FIG. 6 is a schematic plan view illustrating a part of a planar circuit of a superconducting quantum circuit with the airbridge 30 according to the example embodiment. In FIG. 6, two airbridges 30-1 and 30-2 bridge between two conductors 22A and 22B, striding over conductors 21-1 and 21-2, respectively. The airbridges 30-1 and 30-2 have configurations as described in the example embodiments with reference to FIG. 1 etc. That is, plan shapes of the first and second bridge abutments 31-1A and 31-1B of the airbridge 30-1, seen from above, is D-shaped, and planar shapes of the first and second bridge abutments 31-2A and 31-2B of the airbridge 30-2, seen from above, is D-shaped. The conductors 22A, 22B, 21-1, and 21-2 are made of a superconducting material, such as Nb, as described above. The airbridge 30-1 and 30-2 are made of superconducting material(s) and may be made of Al, for example, as described above.

In a SQUID 10, each of Josephson junctions (JJ1 and JJ2) includes a first Al film, an insulating film, and a second Al film, where the first Al film connects to a first superconducting wiring, such as Nb, formed on a substrate, the insulating film of an Al oxide film which is obtained by oxidizing the first Al film and formed on the first Al film, and the second Al film is formed partially overlapping the insulating film and connected to a second superconducting wiring such as Nb. That is, a resist is applied to a substrate (silicon), on which a wiring pattern of a superconducting material such as Nb is formed, exposed and developed to provide a resist bridge above the substrate (silicon) 1, and then a first Al is deposited by tilting the substrate using the resist bridge as a mask, to form a first Al film pattern. Al surface is oxidized in an oxidation chamber, then the substrate is tilted in a reverse direction, and Al is deposited to form a second Al film pattern. As a result, overlapping parts are formed between the first Al film pattern formed by the first oblique deposition and the second Al film pattern formed by the second oblique deposition. These overlapping parts are JJ1 and JJ2, respectively. In FIG. 6, wirings 11 and 12 are wiring patterns of the first and second Al films formed by the first and second oblique depositions. and connect to the first superconducting wirings 21-1 and 21-2 of such as Nb, respectively. The configuration illustrated in FIG. 6 schematically illustrates an example in which the airbridge 30 according to the example embodiment is applied to a superconducting circuit chip including the SQUID 10, but the superconducting circuit chip may, as a matter of course, be not limited to such a configuration.

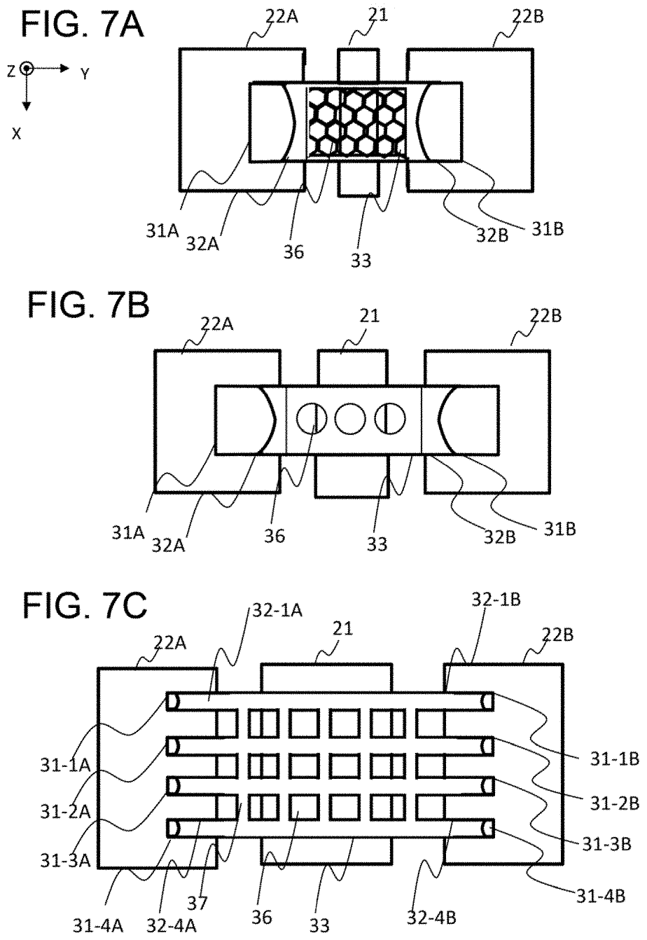

FIG. 7A to FIG. 7C illustrate schematic plan views of examples of other configurations of the airbridge 30 according to the example embodiment. In an example illustrated in FIG. 7A, an airbridge 30 has a mesh structure at least in the bridge girder part 33. In FIG. 7A, a mesh 36 of the mesh structure is hexagonal, but other mesh shapes are possible. For example, in an example illustrated in FIG. 7B, a plurality of round openings forms a mesh 36 in the bridge girder part 33. In the example illustrated in FIG. 7B, three round openings are illustrated, however, the number of openings is, as a matter of course, not limited to three. A mesh size is not limited to that illustrated, and may be, as a matter of course, even smaller or larger. In FIG. 7B, a shape of an opening is not limited to a circular shape. The shape of the mesh (opening) 36 may be, as a matter of course, square, rhombic or oval.

A width of the airbridge 30 (a length covering the third conductor 21) may be larger than that illustrated in the figure. For example, as illustrated schematically in FIG. 7C, a plurality of airbridges are connected at a predetermined interval by lateral members (transverse bars) 37 to form a grid mesh 36. Each airbridge has first bridge abutments 31-1A to 31-4A, and second bridge abutments 31-1B to 31-4B, with a planar shape of each thereof being D-shaped, seen from above. In FIG. 7C, a number of the bridge piers is four of 32-1A to 32-4A (32-1B to 32-4B). The number of the bridge piers, as a matter of course, is not limited to four, and a number of the lateral members 37 is not limited to five. In FIG. 7C, a relationship between a line width of the third conductor (signal conductor) to a size of the grid mesh (opening) 36 is not limited to the example illustrated in FIG. 7C.

In FIG. 7A to 7C, the mesh structure of the airbridge 30 may be formed by forming a mesh pattern on a corresponding part of the bridge piers of the superconductive conductor film 2 in the exposure, development, and etching process of the photoresist 7 illustrated in FIG. 2.

Making the bridge girder part 33 of the airbridge 30 into the mesh structure is effective, for example, in reducing a weight of the bridge girder part 33. By providing openings in the bridge girder part 33, substantial overlapping area(s) between the third conductor 21 and the airbridge 30 thereover is reduced. This may contribute to a reduction in parasitic capacitance therebetween.

The airbridge of the example embodiment has a configuration that interconnects the opposing first and second conductors (ground) striding (i.e., bridging) over the third conductor (signal conductor) provided in a gap therebetween, but is not limited to this configuration. It is, as a matter of course, possible to apply the airbridge for two signal wires that intersect to one another, with one signal wire striding (i.e., bridging) over the other signal wire.

The airbridge 30 of the example embodiment is not limited to a superconducting quantum circuit (quantum device), but may be, as a matter of course, also applied to an MMIC and so forth.

The disclosure of each of the above PTLs 1 to 3 is incorporated herein by reference thereto. Modifications and adjustments of the example embodiments and examples are possible within the scope of the overall disclosure (including the claims) of the present invention and based on the basic technical concept of the present invention. Various combinations or selections of various disclosed elements (including the elements in each of the notes, example embodiments, drawings, etc.) are possible within the scope of the claims of the present invention. That is, the present invention of course includes various variations and modifications that could be made by those skilled in the art according to the overall disclosure including the claims and the technical concept.

What is claimed is:

1. An airbridge comprising:
first and second bridge abutments contacted with first and second conductors, respectively, the first and second conductors opposing each other via a gap, wherein a third conductor is provided extending in the gap, the first to third conductors each provided on a substrate;
first and second bridge piers rising from the first and second bridge abutments, respectively; and
a bridge girder part having both ends supported by the first and second bridge piers in air, the bridge girder part striding over the third conductor, wherein
a first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and
a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

2. The airbridge according to claim 1, wherein the first intersection edge takes a shape of a convex curve protruded against the first virtual straight line toward a direction opposite to a side of the first bridge abutment opposing the first virtual straight line, and
the second intersection edge takes a shape of a convex curve protruded against the second virtual straight line toward a direction opposite to a side of the second bridge abutment opposing the second virtual straight line.

3. The airbridge according to claim 1, wherein the first intersection edge takes a shape of a convex curve protruded against the first virtual straight line toward a side of the first bridge abutment opposing the first virtual straight line, and
the second intersection edge takes a shape of a convex curve protruded against the second virtual straight line toward a side of the second bridge abutment opposing the second virtual straight line.

4. The airbridge according to claim 1, wherein each of the first and second bridge piers has a configuration in which a convex degree of the convex shape corresponding to each of the first and second intersection edges at the bases of the first and second bridge piers is gradually mitigated toward a top of each of the first and second bridge piers.

5. The airbridge according to claim 1, wherein the bridge girder part located at the tops of the first and second bridge piers, has a transverse cross section with flat top and bottom edges.

6. The airbridge according to claim 1, wherein at least the bridge girder part includes a mesh structure.

7. A superconducting circuit apparatus comprising:
first and second conductors arranged opposing each other;
a third conductor extended in a gap between the first and second conductors, the first, second and third conductors each made of a superconducting material; and
an airbridge striding over the third conductor to bridge first and second conductors, wherein the airbridge includes:
first and second bridge abutments contacted with first and second conductors, respectively, the first and second conductors opposing each other via a gap, wherein a third conductor is provided extending in the gap, the first to third conductors provided on a substrate;
first and second bridge piers rising from the first and second bridge abutments, respectively; and
a bridge girder part having both ends supported by the first and second bridge piers in air, the bridge girder part striding over the third conductor, wherein
a first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and
a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

8. The superconducting circuit apparatus according to claim 7, wherein the first intersection edge takes a shape of a convex curve protruded against the first virtual straight line toward a direction opposite to a side of the first bridge abutment opposing the first virtual straight line, and
the second intersection edge takes a shape of a convex curve protruded against the second virtual straight line toward a direction opposite to a side of the second bridge abutment opposing the second virtual straight line.

9. The superconducting circuit apparatus according to claim 7, wherein the first intersection edge takes a shape of a convex curve protruded against the first virtual straight line toward a side of the first bridge abutment opposing the first virtual straight line, and
the second intersection edge takes a shape of a convex curve protruded against the second virtual straight line toward a side of the second bridge abutment opposing the second virtual straight line.

10. The superconducting circuit apparatus according to claim 7, wherein each of the first and second bridge piers has a configuration in which a convex degree of the convex shape corresponding to each of the first and second intersection edges at the bases of the first and second bridge piers is gradually mitigated toward a top of each of the first and second bridge piers.

11. The superconducting circuit apparatus according to claim 7, wherein the bridge girder part located at the tops of the first and second bridge piers, has a transverse cross section with flat top and bottom edges.

12. The superconducting circuit apparatus according to claim 7, wherein at least the bridge girder part includes a mesh structure.

13. The superconducting circuit apparatus according to claim 7, wherein the superconducting circuit apparatus includes:
a plurality of the air bridges separately provided in parallel and striding over the third conductor to bridge first and second conductors; and
a plurality of lateral members provided perpendicular to a longitudinal direction the bridge girder part, the plurality of lateral members connecting the bridge girder parts of the plurality of the air bridges provided at a predetermined interval along a longitudinal direction the bridge girder parts to form a mesh structure.

14. A fabrication method of a superconducting circuit apparatus that includes:
first and second conductors arranged opposing each other;
a third conductor extended in a gap between the first and second conductors, the first, second and third conductors each made of a superconducting material; and
an airbridge striding over the third conductor to bridge first and second conductors, the airbridge including:
first and second bridge abutments contacted with the first and second conductors, respectively;
first and second bridge piers rising from the first and second bridge abutments, respectively; and
a bridge girder part having both ends supported by the first and second bridge piers in air, the bridge girder part striding over the third conductor, the method comprising:
(A) forming first and second vias each having convex shaped bottom apertures protruding toward one side at locations corresponding to locations of formation of the first and second bridge abutments, respectively, on a sacrificial layer formed on a superconducting wiring pattern on a substrate;
(B) depositing a superconducting film, as a component of the airbridge, on the sacrificial layer; and
(C) removing the sacrificial layer after patterning the superconducting film of the component of the airbridge, to produce the airbridge,
wherein a first intersection edge, at which the first bridge abutment intersects with a base of the first bridge pier, is of a convex shape protruded against a first virtual straight line connecting end points of the first intersection edge at which the first intersection edge intersects with both sides of the first bridge abutment, and
a second intersection edge, at which the second bridge abutment intersects with a base of the second bridge pier, is of a convex shape protruded against a second virtual straight line connecting end points of the second intersection edge at which the second intersection edge intersects with both sides of the second bridge abutment.

15. The fabrication method according to claim 14, wherein the first intersection edge takes a shape of a convex curve protruded against the first virtual straight line toward a direction opposite to a side of the first bridge abutment opposing the first virtual straight line, and
the second intersection edge takes a shape of a convex curve protruded against the second virtual straight line toward a direction opposite to a side of the second bridge abutment opposing the second virtual straight line.

16. The fabrication method according to claim 14, wherein the first intersection edge takes a shape of a convex curve protruded against the first virtual straight line toward a side of the first bridge abutment opposing the first virtual straight line, and
the second intersection edge takes a shape of a convex curve protruded against the second virtual straight line toward a side of the second bridge abutment opposing the second virtual straight line.

17. The fabrication method according to claim 14, comprising
forming the first and second bridge piers such that a convex degree of the convex shape corresponding to each of the first and second intersection edges at the bases of the first and second bridge piers is gradually mitigated toward a top of each of the first and second bridge piers.

18. The fabrication method according to claim 14, comprising
forming the bridge girder part located at the tops of the first and second bridge piers, to have a transverse cross section with flat top and bottom edges.

19. The fabrication method according to claim 14, comprising
providing a mesh structure in at least the bridge girder part.
